(19) United States
(12) Patent Application Publication
(10) Pub. No.: US 2005/0124128 A1
(43) Pub. Date: Jun. 9, 2005

(54) Methods for manufacturing semiconductor device

(76) Inventor: Hag Dong Kim, Suwon-si (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/008,524

(22) Filed: Dec. 8, 2004

(30) Foreign Application Priority Data
Dec. 8, 2003 (KR) 10-2003-0088567
Dec. 8, 2003 (KR) 10-2003-0088564

(51) Int. Cl. H01L 21/336

(52) U.S. Cl. 438/305

(57) ABSTRACT

Methods of forming a silicide layer with small grain boundary size on a source/drain region of semiconductor device are disclosed. A disclosed method comprises forming a gate insulating layer and a gate electrode on an active region of a semiconductor substrate; forming spacers on the sidewalls of the gate electrode; implanting impurity ions for a source/drain region at a high concentration by using the gate electrode and the spacers as an ion implantation mask; depositing an interlayer dielectric layer over the semiconductor substrate including the gate electrode and the spacers; forming contact holes through the interlayer dielectric layer; depositing a barrier metal layer for silicide layers along the top surface of the interlayer dielectric layer and along the sidewalls and the bottoms of the contact holes; and performing a thermal treatment process to complete a source/drain region in the active region and form silicide layers on the source/drain region and the gate electrode.

### FIELD OF THE DISCLOSURE

The present disclosure relates to methods of fabricating a semiconductor device and, more particularly, to methods for reducing the grain boundary size of a silicide layer formed on a source/drain region to decrease the contact resistance in a source/drain region of semiconductor devices.

### BACKGROUND

As semiconductor devices become more highly integrated, the sizes of the semiconductor devices decrease. The metal-oxide-silicon (MOS) transistor of semiconductor device is thus gradually downsized. In other words, the size of elements constituting the MOS transistor, such as source/drain regions, gate electrodes, and metal wires, is gradually reduced. In addition, contact holes, which electrically connect the source/drain region with the metal wire or the gate electrode with the metal wire, are also downsized. Such miniaturization of the contact holes may increase the contact resistance of the contact holes, thereby delaying the transfer of electrical signal and reducing the operation speed of the semiconductor device.

Consequently, to meet the increasing requirement for increased speed within a semiconductor device (e.g., higher clock frequencies), technologies for reducing the contact resistance have been developed. Among them, particularly, silicide technology, which forms a silicide layer on the source/drain region, has widely been employed. The earlier silicide process forms the silicide layer on the source/drain region and the gate electrode respectively by using separate steps. Therefore, the earlier silicide process has several problems such as a complicated manufacturing process and high production cost.

Recently, a salicide (self-aligned silicide) process has been developed to simplify the silicide process and curtail the production cost. The salicide process forms the silicide layer both on the gate electrode and on the source/drain region at the same time by using one process. In detail, the salicide process includes depositing simultaneously a refractory metal layer on a single crystal silicon layer, a polysilicon layer, and an insulating layer, and performing heat treatment to the refractory metal layer. By the heat treatment, the refractory metal layers on the single crystal silicon layer and the polysilicon layer are silicided but the same on the insulating layer are not silicided to remain its characteristics. The unsilicided refractory metal layer is removed by using an etching process and, therefore, the silicide layers remain on the single crystal silicon and polysilicon layers. Among various salicide processes, particularly, titanium salicide process and cobalt salicide process are widely used in manufacturing semiconductor devices.

FIG. 1 is a cross-sectional view of the semiconductor device fabricated by a known salicide process. As shown in FIG. 1, device isolation layers 11 are formed in field regions of a semiconductor substrate 10 to define at least one active region of the semiconductor substrate 10. A gate insulating layer 13 and a gate electrode 15 are formed on the active region of semiconductor substrate 10. Spacers 17 are then formed on the sidewalls of the gate electrode 15. A source/drain (S/D) region with a lightly doped drain (LDD) structure is formed in the semiconductor substrate 10. Silicide layers 25 and 27 are formed on the S/D region and the gate electrode 15 within contact holes formed through an interlayer dielectric (ILD) layer 20. The ILD layer 20 consists of a borophospho silicate glass (BPSG) layer 21 and a tetra ethyl ortho silicate (TEOS) layer 23. The silicide layers 25 and 27 include a Ti silicide layer.

In the known salicide process, the S/D junction is formed by implanting impurities into the active region of the semiconductor substrate 10 and diffusing the implanted impurities through rapid thermal treatment. Here, the rapid thermal treatment is performed at a temperature between 900° C. and 1000° C. for 10˜20 seconds. The ILD layer 20 is then deposited over the resulting structure and contact holes are formed through the ILD layer 20. Next, a Ti/TiN layer is deposited along the top surface of the ILD layer 20 and the bottoms and the sidewalls of the contact holes. Next, by performing rapid thermal treatment for the Ti/TiN layer at a temperature between 700° C. and 800° C. for 10˜20 seconds, the Ti/TiN layer is silicided to form a silicide layer 25 on the S/D region.

However, the silicide layer 25 has a large grain boundary size and a large resistance because it is formed on the S/D region, which is not amorphous. As a result, the contact resistance between the S/D region and a metal wire (not shown) increases and, as a result, the operation speed of semiconductor device is lowered. In addition, the thermal treatments to form the S/D junction and the silicide layer 25 are increase the complexity of the manufacturing process and the production cost.

### BRIEF DESCRIPTION OF THE DRAWINGS

FIG. 1 is a cross-sectional view of a semiconductor device fabricated by a known salicide process.

FIGS. 2a through 2g are cross-sectional views illustrating an example process of fabricating a semiconductor device.

FIGS. 3a through 3h are cross-sectional views illustrating another example process of fabricating a semiconductor device.

FIGS. 4a through 4e are cross-sectional views illustrating another example process of fabricating a semiconductor device.

### DETAILED DESCRIPTION

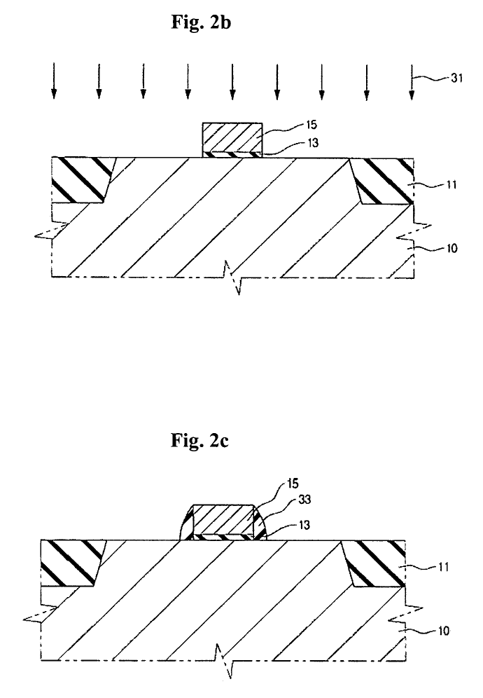

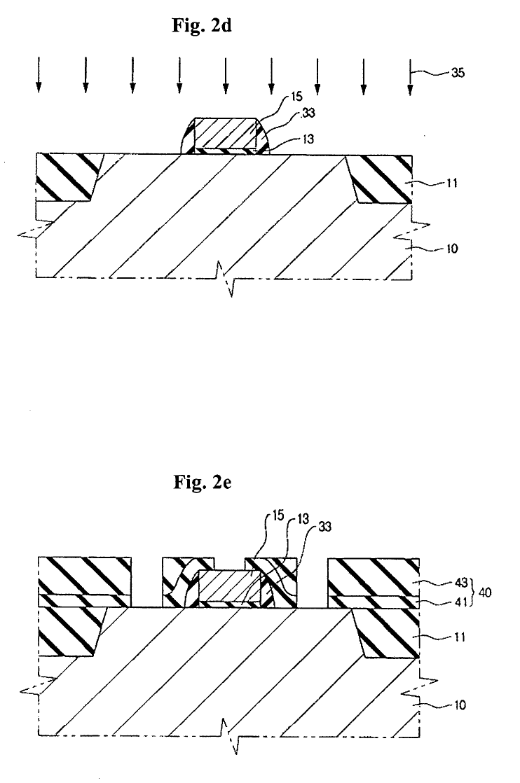

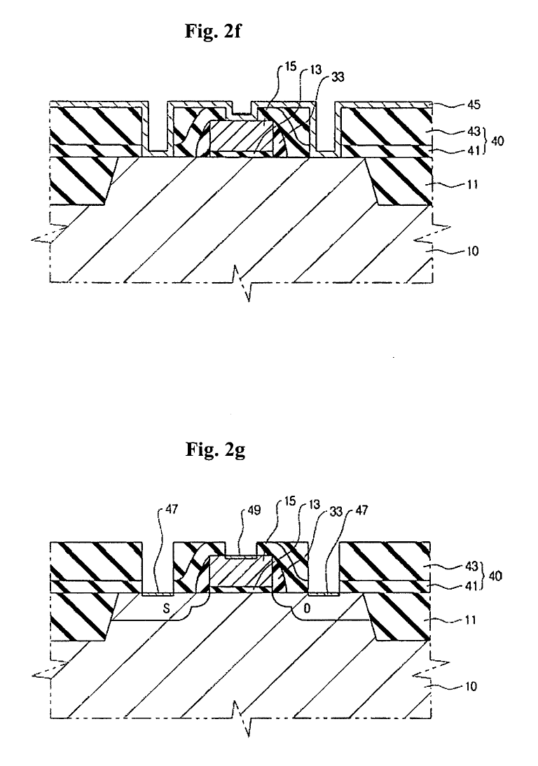

FIGS. 2a through 2g are cross-sectional views illustrating an example process of fabricating a semiconductor device.

Referring to FIG. 2a, a semiconductor substrate 10, for example, single crystal silicon of a first conduction type, is prepared. The first conduction type may be a p-type or n-type. For convenience of illustration, this disclosure illustrates an example process of using a p-type semiconductor substrate. Device isolation layers 11 are formed in field regions of the semiconductor substrate 10 to define at least one active region of the semiconductor substrate 10. The device isolation layers 11 are formed by an STI (shallow trench isolation) process. The isolation layers 11 may also be formed by a LOCOS (local oxidation of silicon) process. An insulating layer is formed on the active region of the semiconductor substrate 10. A polysilicon layer is then deposited on the insulating layer. Some part of the insulating layer and the polysilicon layer is removed by a photolithography process to form a gate electrode 15 of polysilicon and a gate insulating layer 13 on the active region of the semiconductor substrate 10.

Referring to FIG. 2b, an ion implantation process is performed by using the gate electrode 15 as an ion implantation mask to implant impurities 31 for LDD structure at a low concentration, for example, n-type impurities. Here, although it is not shown, the region for PMOS transistor of the semiconductor substrate 10 is masked with a predetermined photoresist pattern.

Referring to FIG. 2c, an insulating layer, preferably, a nitride layer is deposited over the resulting structure by a chemical vapor deposition. By performing an etch back process for the nitride layer, spacers 33 are formed on the sidewalls of the gate electrode 15 and the gate insulating layer 13. The top surface of the gate electrode 15 and the active region around the gate electrode 15 are exposed. The spacers 33 may be formed using oxide layer or multi-layer of oxide and nitride layer.

Referring to FIG. 2d, an ion implantation process is performed by using the spacers 33 and the gate electrode 15 as an ion implantation mask to implant impurities 35 for a S/D region at a high concentration, for example, n-type impurities, into the active region of the semiconductor substrate 10. Therefore, the active region into which ions are implanted is changed from single crystal silicon to amorphous silicon. Here, although it is not shown, the region for PMOS transistor of the semiconductor substrate 10 is masked with a predetermined photoresist pattern.

Referring to FIG. 2e, an ILD layer 40, preferably an oxide layer, is deposited over the resulting structure. In detail, a first insulating layer, for example, BPSG layer 41 is deposited over the resulting structure and a second insulating layer, for example, TEOS layer 43 is then deposited on the BPSG layer 41. Next, the TEOS layer 43 is planarized by using a chemical mechanical polish process. In the illustrated example, the ILD layer 40 may comprise various applicable single layers or multi-layers.

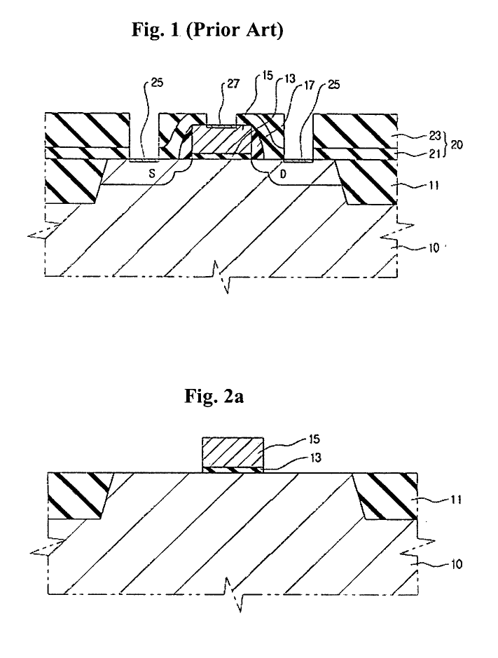

Particularly, in the illustrated example, a thermal treatment process for diffusing the implanted impurities for the S/D region is omitted and the ILD layer 40 is directly deposited over the resulting structure. This omission is for forming a silicide layer with smaller grain boundary size than that of the conventional silicide layer 25 of FIG. 1 by subsequent later processes. Next, some part of the ILD layer 40 is removed by using a photolithography process to form contact holes on the S/D region and the gate electrode 15.

Referring to FIG. 2f, a barrier metal layer is deposited along the top surface of the ILD layer 40 and along the bottoms and the sidewalls of the contact holes by a sputtering process or chemical vapor deposition process. The barrier metal layer is preferably a Ti/TiN layer 45 comprising a Ti layer and a TiN layer with a thickness between about 50 Å and about 300 Å, respectively. Instead of the Ti/TiN layer, a single Ti layer may be used as the barrier metal layer. Next, a thermal treatment, preferably a rapid thermal treatment, is performed for the Ti/TiN layer 45 at a temperature between about 800° C. and about 1050° C. for about 10 seconds to about 30 seconds. Here, the thermal treatment is carried out under an inert gas, for example, nitrogen gas atmosphere. Through the thermal treatment, the Ti/TiN layer 45 is silicided and the implanted impurities are activated. Subsequently, the unsilicided Ti/TiN layer on the ILD layer 40 is removed by a wet etch process. Consequently, as shown in FIG. 2g, a silicide layer 47 is formed on the active region of amorphous state and a silicide layer 49 is formed on the gate electrode 15. At the same time, the S/D junction with LDD structure is completed in the active region.

Accordingly, the illustrated process achieve the silicide layer 47 with a smaller grain boundary size than that of the conventional silicide layer 25 of FIG. 1, which is formed on the S/D region of single crystal state, so that the resistance of the silicide layer 47 lowers in comparison with that of the conventional silicide layer 25. Such decrease in the resistance of the silicide layer 47 reduces the contact resistance between the S/D region and a metal wire (not shown) to suppress the transfer delay of an electrical signal and enhance the operation speed of semiconductor device.

In addition, by simultaneously forming the silicide layers and the S/D junction by using one thermal treatment, the illustrated process simplifies the semiconductor device fabrication process and, therefore, reduces the production cost in comparison with the conventional process, which forms the silicide layers and the S/D junction, respectively, by using separate heat treatments.

Subsequently, a semiconductor device is completed by performing later unit processes comprising depositing a barrier metal layer along the top surface of the ILD layer and along the sidewalls and the bottoms of the contact holes, filling the contact holes with a metal, for example, tungsten, planarizing the tungsten layer, and electrically connecting the tungsten layer with a metal wire pattern on the ILD layer.

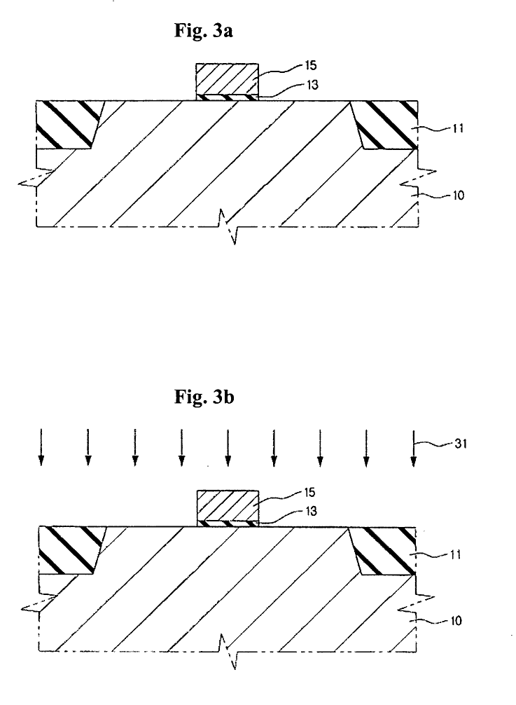

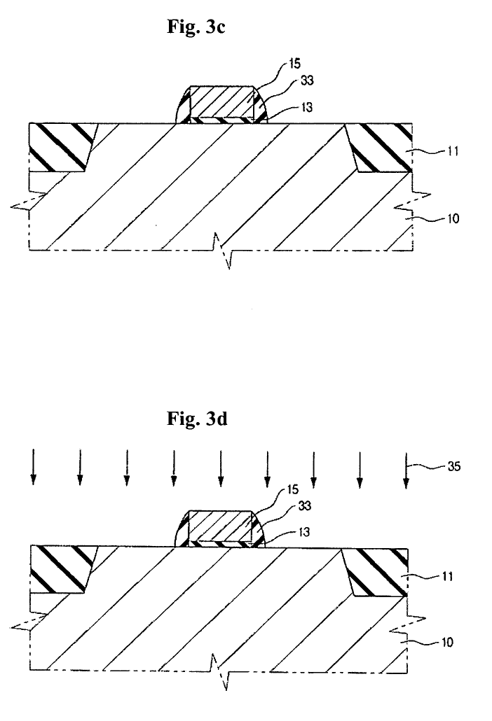

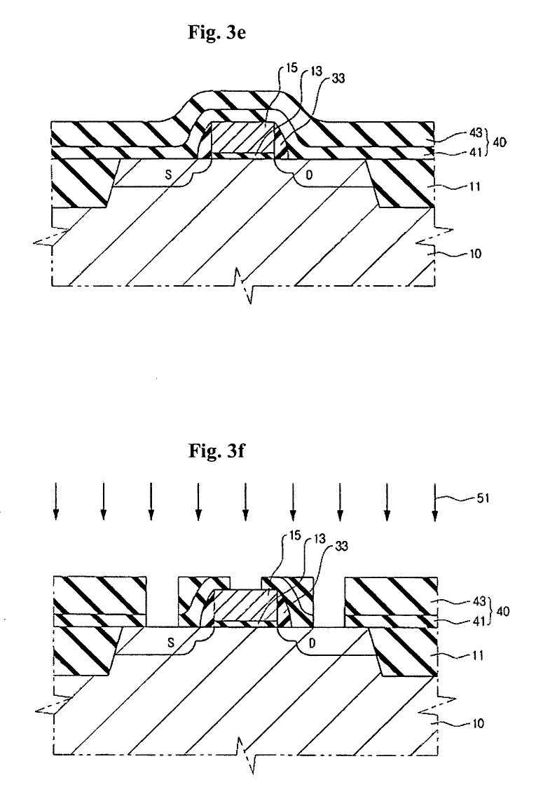

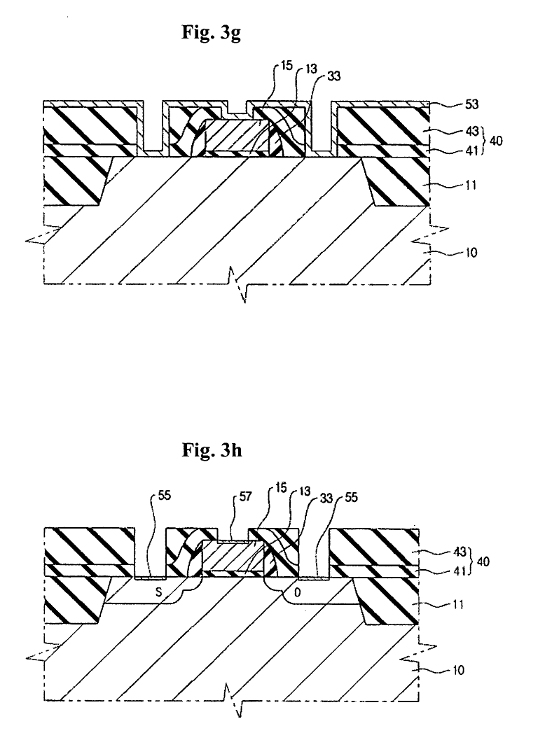

FIGS. 3a through 3h are cross-sectional views illustrating another example process of fabricating a semiconductor device.

Referring to FIG. 3a, a semiconductor substrate 10, for example, single crystal silicon of a first conduction type, is prepared. The first conduction type may be a p-type or n-type. For convenience of illustration, this disclosure illustrates an example process of using a p-type semiconductor substrate. Device isolation layers 11 are formed in field regions of the semiconductor substrate 10 to define at least one active region of the semiconductor substrate 10. The device isolation layers 11 are formed by STI (shallow trench isolation) or LOCOS (local oxidation of silicon). An insulating layer is formed on the active region of the semiconductor substrate 10. A conductive layer, preferably, a polysilicon layer is then deposited on the insulating layer. Some part of the insulating layer and the polysilicon layer is removed by a photolithography process to form a gate electrode 15 of polysilicon and a gate insulating layer 13 on the active region of the semiconductor substrate 10.

Referring to FIG. 3b, an ion implantation process is performed by using the gate electrode 15 as an ion implantation mask to implant impurities 31 for LDD structure at a low concentration, for example, n-type impurities. Here, although it is not shown, the region for PMOS transistor of the semiconductor substrate 10 is masked with a predetermined photoresist pattern.

Referring to FIG. 3c, an insulating layer, for example, a nitride layer is deposited over the resulting structure by a chemical vapor deposition process. Then, by performing an etch back process for the nitride layer, spacers 33 are formed on the sidewalls of the gate electrode 15 and the gate insulating layer 13. The top surface of the gate electrode 15 and the active region around the gate electrode 15 are exposed. The spacers 33 may be formed using oxide layer or multi-layer of oxide and nitride.

Referring to FIG. 3d, an ion implantation process is performed by using the gate electrode 15 and the spacers 33 as an ion implantation mask to implant impurities 35 for an S/D region at a high concentration, for example, n-type impurities, into the active region. Here, although it is not shown, the region for PMOS transistor of the semiconductor substrate 10 is masked with a predetermined photoresist pattern.

Referring to FIG. 3e, a thermal treatment process is performed for the resulting structure in order to diffuse the impurities for the LDD structure and impurities for the S/D region and complete the S/D junction with the LDD structure. Next, an ILD layer 40, for example, an oxide layer, is deposited over the resulting structure. In detail, a first insulating layer, for example, a BPSG layer 41 is deposited on the resulting substrate and a second insulating layer, for example, a TEOS layer 43 is formed on the BPSG layer 41. In this illustrated example, the ILD layer 40 may comprise various applicable single layers or multi-layers. Next, some part of the ILD layer 40 is removed by using a photolithography process to form contact holes on the S/D region and the gate electrode 15.

Referring to FIG. 3f, the TEOS layer 43 is planarized by using a planarization process, for example, a chemical mechanical polish process. Some part of the ILD layer is then removed to form contact holes on the S/D region and the gate electrode 15, respectively. Next, an ion implantation process is performed for the resulting structure to implant ions for amorphizing the S/D region, for example, Ge ions. The Ge ions are implanted at a dose between about 1E14 ions/cm² and about 1E15 ions/cm² under an energy level between about 10 keV and about 50 keV. Thus, the portion near the surface of the S/D region within the contact hole is amorphized. By amorphizing the surface of S/D region within the contact hole, the silicide layer to be formed by later processes has a smaller drain boundary size than that of the conventional silicide layer and, thereby, the resistance of the silicide layer is reduced. The Ge ions may be implanted into both the region for NMOS transistor and the region for PMOS transistor. In this illustrated example, Si ions may be used instead of the Ge ions.

Referring to FIG. 3g, a barrier metal layer such as a Ti/TiN layer 53 is deposited along the top surface of the ILD layer 40 and along the sidewalls and the bottoms of the contact holes by using a predetermined unit process, for example, a sputtering process. The Ti/TiN layer 53 comprises a Ti layer and a TiN layer with a thickness between about 50 Å and about 300 Å, respectively. Instead of the Ti/TiN layer, a Ti layer may be used as the barrier metal layer.

Referring to FIG. 3h, a thermal treatment process, preferably a rapid thermal treatment, is performed for the Ti/TiN layer 53 at a temperature between about 600° C. and about 800° C. for about 10 seconds to about 60 seconds. The rapid thermal treatment is preferably carried out under an inert gas, for example, nitrogen gas atmosphere. Through such thermal treatment, the Ti/TiN layer 53 is silicided. The unsilicided Ti/TiN layer on the ILD layer 40 is then removed by using a wet etch process. Thus, a silicide layer 55 is formed on the amorphized S/D region and a silicide layer 57 is formed on the gate electrode 15.

Particularly, the silicide layer 55 on the S/D region has a smaller grain boundary size than that of the conventional silicide layer 25 of FIG. 1 which is formed on the S/D region of single crystal state. Such decrease in the grain boundary size reduces the resistance of the silicide layer 55 in comparison with that of the conventional silicide layer 25. Further, the low resistance of the silicide layer 55 reduces the contact resistance between the S/D region and a metal wire (not shown) to suppress the transfer delay of an electrical signal and enhance the operation speed of semiconductor device.

Subsequently, a semiconductor device is completed by performing later unit processes comprising depositing a barrier metal layer along the top surface of the ILD layer and along the sidewalls and the bottoms of the contact holes, filling the contact holes with a metal, for example, tungsten, planarizing the tungsten layer, and electrically connecting the tungsten layer with a metal wire pattern on the ILD layer.

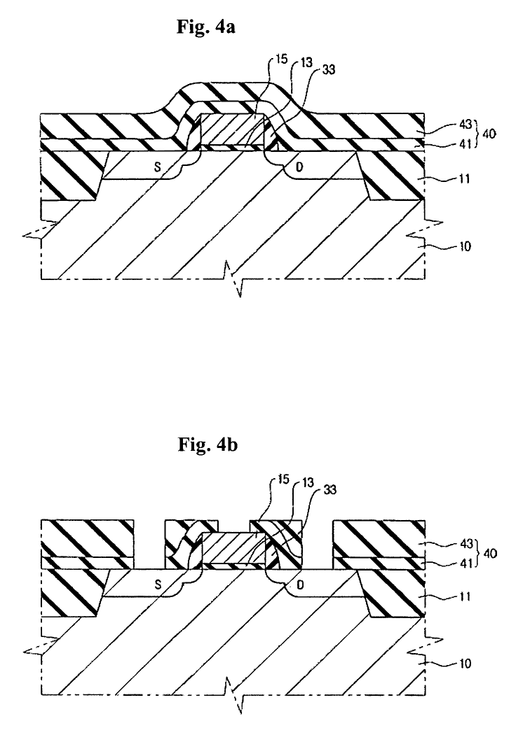

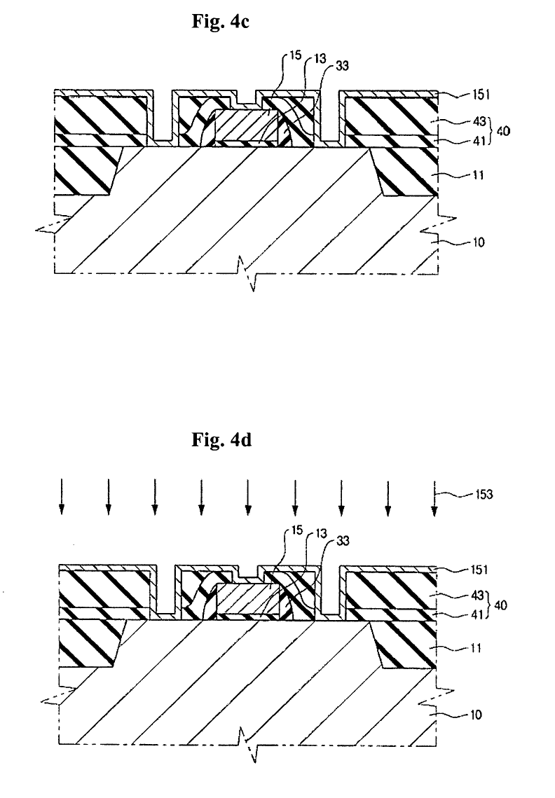

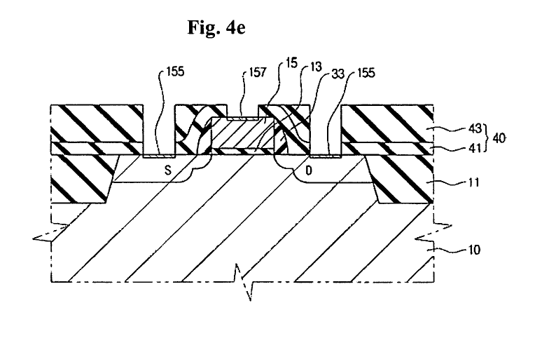

FIGS. 4a through 4e are cross-sectional views illustrating another example process of fabricating a semiconductor device.

Referring to FIG. 4a, by performing the unit processes according to FIGS. 3a through 3e, device isolation layers 11, a gate insulating layer 13, a gate electrode 15, spacers 33, and a S/D region with LDD structure are formed on a semiconductor substrate 10. Then, an ILD layer 40 comprising a BPSG layer 41 and a TEOS layer 43 is formed on the resulting structure.

Referring to FIG. 4b, the TEOS layer 43 is planarized by a planarization process such as chemical mechanical polish. Some portion of the ILD layer 40 is then removed by using a photolithography process to form contact holes on the S/D region and the gate electrode 15, respectively.

Referring to FIG. 4c, a barrier metal layer such as a Ti/TiN layer 151 is deposited along the top surface of the ILD layer 40 and along the sidewalls and the bottoms of the contact holes by using a predetermined unit process, for example, a sputtering process. The Ti/TiN layer 151 comprises a Ti layer and a TiN layer with a thickness between about 50 Å and about 300 Å, respectively. A Ti layer may be used as the barrier metal layer instead of the Ti/TiN layer 151.

Referring to FIG. 4d, an ion implantation process is performed to implant impurity ions 153 for reducing a grain boundary size into the Ti/TiN layer 151. The ions preferably have the same conduction type with the S/D region. By implanting the ions into the Ti/TiN layer 151, the grain boundary size of the Ti/TiN layer 151 is considerably reduced in comparison with that of the original Ti/TiN layer without ions implanted.

In this illustrated example, when the ions are implanted into the region for NMOS transistor, an ion implantation mask layer such as a photoresist pattern, which exposes the region for NMOS transistor and covers the region for PMOS transistor, is formed on the resulting structure by using a photolithography process. Then, the ions, for example, n-type impurity ions such as arsenic or phosphorus ions are implanted into the Ti/TiN layer 151 on the region for NMOS transistor. The arsenic ions are preferably implanted at a dose between about 1E14 ions/cm² and about 1E15 ions/cm² under an energy level between about 30 keV and about 70 keV. The phosphorus ions are preferably implanted at a dose between about 1E14 ions/cm² and about 1E15 ions/cm² under an energy level between about 10 keV and about 40 keV.

Next, when the ions are implanted into the region for PMOS transistor, the photoresist pattern is removed and another ion implantation mask layer such as a photoresist pattern, which exposes the region for PMSO transistor and covers the region for NMOS transistor, is formed on the resulting structure by a photolithography process. The ions 153, for example, p-type impurity ions such as boron (B) or BF₂ ions are implanted into the Ti/TiN layer 151 on the region for PMOS transistor. The B ions are preferably implanted at a dose between about 1E14 ions/cm² and about 1E15 ions/cm² under an energy level between about 2 keV and about 15 keV. The BF₂ ions are preferably implanted at a dose between about 2E14 ions/cm² and about 2E15 ions/cm² under an energy level between about 10 keV and about 50 keV.

Referring to FIG. 4e, a thermal treatment, for example, a rapid thermal treatment, is performed for the Ti/TiN layer 151 at a temperature between about 600° C. and about 800° C. for about 10 seconds to about 60 seconds. The thermal treatment is carried out under an inert gas, for example, nitrogen gas atmosphere. Through the thermal treatment, the Ti/TiN layer 151 is silicided. Subsequently, the unsilicided Ti/TiN layer on the ILD layer 40 is removed by using a wet etch process. Thus, a silicide layer 155 is formed on the S/D region and a silicide layer 157 is formed on the gate electrode 15.

In this illustrated example, particularly, the silicide layer 155 formed on the S/D region has a smaller grain boundary size than that of the conventional silicide layer 25 of FIG. 1 because the impurity ions were implanted into the Ti/TiN layer 151 in the previous unit process. Such reduction of a grain boundary size decreases the resistance of the silicide layer 155 compared to that of the conventional silicide layer 25, thereby reducing the contact resistance between the S/D region and a metal wire (not shown), suppressing the transfer delay of an electrical signal, and further enhancing the operation speed of a semiconductor device.

Subsequently, a semiconductor device is completed by performing later unit processes comprising depositing a barrier metal layer along the top surface of the ILD layer and the sidewalls and the bottoms of the contact holes, filling the contact holes with metal, for example tungsten, planarizing the tungsten layer, and electrically connecting the tungsten layer with a metal wire pattern on the ILD layer.

From the foregoing, persons of ordinary skill in the art will appreciate that, by implanting impurity ions into the barrier metal layer for a silicide layer or into the semiconductor substrate including the S/D region and forming the silicide layer with a small grain boundary size, the disclosed methods reduce the contact resistance of the S/D region, thereby enhancing the operation speed of a semiconductor device. In addition, by simultaneously forming the S/D junction and the silicide layer through only one thermal treatment process, the disclosed methods simplify the fabrication process and reduce the production cost.

It is noted that this patent claims priority from Korea Patent Application Serial Number 10-2003-0088564, which was filed on Dec. 8, 2003, and from Korean Patent Application Serial Number 10-2003-0088567, which was filed on Dec. 8, 2003; both of which are hereby incorporated by reference in their entireties.

Although certain example methods, apparatus and articles of manufacture have been described herein, the scope of coverage of this patent is not limited thereto. On the contrary, this patent covers all methods, apparatus and articles of manufacturing fairly falling within the scope of the appended claims either literally or under the doctrine of equivalents.

1. A method of fabricating a semiconductor device comprising:
forming a gate electrode on an active region of a semiconductor substrate;
forming spacers on the sidewalls of the gate electrode;
implanting impurity ions for a source/drain region at a high concentration into the active region of the semiconductor substrate by using the gate electrode and the spacers as an ion implantation mask;
depositing an interlayer dielectric layer over the semiconductor substrate including the gate electrode and the spacers;
forming contact holes through the interlayer dielectric layer, wherein the contact holes expose some portion of the top surface of the source/drain region and the gate electrode;
depositing a barrier metal layer for silicide layers along the top surface of the interlayer dielectric layer and along the sidewalls and the bottoms of the contact holes; and
performing a thermal treatment process to activate the impurity ions in the source/drain region and form silicide layers on the source/drain region and the gate electrode.

2. A method as defined by claim 1, wherein the thermal treatment process is a rapid thermal treatment process, which is performed in an inert gas atmosphere at a temperature between about 800° C. and about 1050° C. for about 10 seconds to about 30 seconds.

3. A method as defined by claim 1, wherein the barrier metal layer is a Ti/TiN layer.

4. A method of fabricating a semiconductor device comprising:
forming a source/drain region in an active region of a semiconductor substrate on which a gate insulating layer and a gate electrode are formed, wherein the gate insulating layer and gate electrode are positioned between the source region and the drain region;
depositing an interlayer dielectric layer over the semiconductor substrate including the gate electrode;
forming contact holes through the interlayer dielectric layer, wherein the contact holes expose some portion of the top surface of the gate electrode and the source/drain region;
implanting impurity ions into the source/drain region;
depositing a barrier metal layer along the top surface of the interlayer dielectric layer and along the sidewalls and the bottoms of the contact holes; and
performing a thermal treatment process to form a silicide layer on the source/drain region.

5. A method as defined by claim 4, wherein the impurity ions are Ge ions or Si ions.

6. A method as defined by claim 5, wherein the impurity ions are implanted at a dose between about 1E14 ions/cm² and about 1E15 ions/cm² under an energy level between about 10 keV and about 50 keV.

7. A method as defined by claim 4, wherein the barrier metal layer is a Ti/TiN layer.

8. A method as defined by claim 4, wherein the thermal treatment process is a rapid thermal treatment process, which is performed for about 10 seconds to about 60 seconds at a temperature between about 600° C. and about 800° C. in an inert gas atmosphere.

9. A method of fabricating a semiconductor device comprising:
forming a source/drain region in an active region of a semiconductor substrate on which an gate insulating layer and a gate electrode are formed, wherein the gate insulating layer and gate electrode are positioned between the source region and the drain region;
depositing an interlayer dielectric layer over the semiconductor substrate including the gate electrode;
forming contact holes through the interlayer dielectric layer, wherein the contact holes expose some portion of the top surface of the gate electrode and the source/drain region;
depositing a barrier metal layer along the top surface of the interlayer dielectric layer and along the sidewalls and the bottoms of the contact holes;
implanting impurity ions into the barrier metal layer; and
performing a thermal treatment process to form a silicide layer on the source/drain region.

10. A method as defined by claim 9, wherein the impurity ions have the same conduction type as that of the source/drain region.

11. A method as defined by claim 10, wherein the impurity ions are B ions or BF₂ ions and are implanted into the barrier metal layer on the region for PMOS transistor of the semiconductor substrate.

12. A method as defined by claim 11, wherein the B ions are implanted at a dose of between about 1E14 ions/cm² and about 1E15 ions/cm² under an energy level between about 2 keV and about 15 keV.

13. A method as defined by claim 11, wherein the BF₂ ions are implanted at a dose of between about 2E14 ions/cm² and about 2E15 ions/cm² under an energy level between about 10 keV and about 50 keV.

14. A method as defined by claim 10, wherein the impurity ions are As ions or P ions and are implanted into the barrier metal layer on the region for NMOS transistor of the semiconductor substrate.

15. A method as defined by claim 14, wherein the As ions are implanted at a dose of between about 1E14 ions/cm² and about 1E15 ions/cm² under an energy level between about 30 keV and about 70 keV.

16. A method as defined by claim 14, wherein the P ions are implanted at a dose of between about 1E14 ions/cm² and about 1E15 ions/cm² under an energy level between about 10 keV and about 40 keV.

17. A method as defined by claim 9, wherein the barrier metal layer is a Ti/TiN layer.

18. A method as defined by claim 9, wherein the thermal treatment process is a rapid thermal treatment process, which is performed for about 10 seconds to about 60 seconds at a temperature between about 600° C. and about 800° C. in an inert gas atmosphere.
